(19) United States
(12) Patent Application Publication
(10) Pub. No.: US 2009/0221426 A1
(43) Pub. Date: Sep. 3, 2009

(54) Enhanced heat transfer from an HTS element in a cryogenic bath

(75) Inventor: Drew Willard Hazelton, Selkirk, NY (US)

Correspondence Address: George L. Rideout, Jr., 4400 Abbott Grove Drive, Crestwood, KY, 40014, US

(73) Assignee: SuperPower, Inc.

(21) Appl. No.: 11/321,846

(22) Filed: Dec. 29, 2005

(51) Int. Cl. H01L 39/02; F17C 3/00; F25D 3/10; H01L 39/24

(52) U.S. Cl. 505/150; 62/51.1; 505/470; 29/599; 361/19; 174/15.5

(57) ABSTRACT

The fault current limiter in a cryogenic liquid heat transfer medium, employs a high temperature superconductor (HTS) element which has a high thermal resistance coating material encapsulating the high temperature superconductor to form an intermediate boundary layer between the HTS element and the heat transfer medium. The coating material has a thickness which enables it to minimize the retained heat in the HTS element during recovery from a fault condition, wherein substantially all heat transfer from the encapsulated high temperature superconductor element to the liquid cryogen heat transfer medium occurs at the nucleate boiling heat transfer rate.

The U.S. government has a paid-up license in this invention and the right in limited circumstances to require the patent owner to license others on reasonable terms as provided for in the terms of Contract No. DE-FC36-03G013033 awarded by the Department of Energy.

### BACKGROUND

The invention relates generally to heat transfer of HTS elements, and more particularly to enhanced heat transfer from an HTS element in a liquid cryogen bath.

There exist HTS cooling systems that use the properties of liquid nitrogen or other cryogenic liquids to achieve cryogenic cooling. An example of a cryogenic liquid used for cooling would be liquid nitrogen, used at one atmospheric pressure (˜0.1 MPa) where its saturated temperature (boiling point) is at 77 Kelvin. However, since the critical current density of HTS materials improves significantly at temperatures lower than 77 K, methods have been developed to reduce the temperature of the liquid nitrogen by manipulating its operating environment. By reducing the pressure of liquid nitrogen, its boiling point temperature can be lowered to about 63 K below which solid nitrogen would form. One example of using such properties of liquid nitrogen to achieve lower operating temperature is provided in U.S. Pat. No. 5,477,693. It describes a method of using a vacuum pump to pump the gaseous nitrogen region in a cryogen containment vessel (cryostat) that contains both the liquid and gaseous nitrogen. Pumping reduces the pressure of the liquid nitrogen bath therefore reducing its saturation temperature (boiling point) to below 77 K. The performance of the superconductor when cooled to this reduced temperature, namely its critical current level, is then significantly improved.

During the electrical transient in an FCL device associated with a fault on the electric power grid, the essentially adiabatic, rapid temperature rise of the high-temperature superconductor elements can result in a nominal element temperature rise of 200 to 300 K. With these rapidly heated elements submerged within the bath of liquid nitrogen, the large difference between the surface temperature of the element and the temperature of the surrounding bath results in an almost instantaneous initiation of film boiling of the liquid nitrogen bath at the interface. Film boiling is the formation of a stable vapor layer between the heated element and the liquid nitrogen bath. The thermal heat transfer across this vapor layer is limited by the thermal conductivity of the vapor and results in a relatively low cooling rate of the HTS element as it recovers after the fault. This recovery can be described as a re-cooling of the HTS element to below its critical temperature so that its superconducting properties are regained. This situation is complicated further if an electric current is applied to the element after the fault, resulting in added heat load to the element which must be removed during recovery. This added condition is called Recovery Under Load (RUL).

Under film boiling conditions, the heat transfer from the HTS element to the surrounding cryogen bath is known to employ the film boiling portion of a boiling heat transfer curve, line 12 for the case of liquid nitrogen, in plot 10 in FIG. 1. This figure illustrates the boiling heat transfer from a heated element to saturated liquid nitrogen at one atmospheric pressure. The heat transfer (Watts/cm²) is given vs. the temperature difference (T_{wall}−Tₛₐₜ) between the surface (wall) temperature of the heated element and the saturation temperature of the cryogen bath. For example, the rapid heating of the HTS element results in an initial ΔT, (T_{wall}−Tₛₐₜ), of approximately 100 to 200 K, the heat transfer from the FCL HTS elements to the saturated LN2 bath in the film boiling state, is on the order of 1.3 to 2.6 Watts per cm², dropping down to 0.6 Watts per cm² as the element cools to a (T_{wall}−Tₛₐₜ) of ˜35 K. It is, however, desirable to maintain the HTS heat transfer rate in the nucleate boiling state 16 wherein ΔT, (T_{wall}−Tₛₐₜ), is less than about 10 and the heat transfer rates can be as high as 10 W/cm².

It is known to utilize a nylon wire mesh in conjunction with a perforated outer tube to ensure the free circulation of cooling fluid, liquid or gas around the surface of the conductor to facilitate heat recovery, as is disclosed in U.S. Pat. No. 5,432,666. It is also known to use coatings to modify the heat transfer characteristics of a surface in a cryogenic liquid. For example, in the publication by R F Barron, entitled, Cryogenic Heat Transfer, section 2.7 and the publication by M N Wilson, entitled Superconducting Magnets, section 6.5 the use of coatings is taught to enhance heat transfer characteristics.

It is also known to add to superconductive paste comprising Bi, Pb, Sr, Ca and Cu and an organic binder, which may be applied to the surface of the substrate material having a thickness of about 100 μm, or more, wherein the paste is heated to form a coating encapsulating the substrate material, as disclosed in U.S. Pat. No. 6,809,042. The resulting HTS element thus will have an enhanced high critical current and critical magnetic field.

It is further known to add epoxy encapsulation around the HTS element to thermally isolate the superconductor material from the cooling medium and decrease the critical current density of the superconductor material wherein the epoxy is less than 2 mm thick and has thermal expansion properties approximately equal to the thermal expansion properties of the superconducting material, as disclosed in U.S. Pat. No. 5,761,017. The purpose of such encapsulation is to dissipate heat as quickly as possible, as disclosed, for example, in column 5, lines 6-9. However, as shown in FIG. 3 of the '017 patent and as referenced in column 5, lines 9-14, the heat dissipation into the epoxy does not extend to the surface of the epoxy in contact with the cooling medium. In addition, this patent does not disclose or teach the use of an intermediate boundary layer to enhance heat transfer and to maximize heat transfer from the HTS element to a surrounding liquid cryogen cooling bath through the encapsulation by promoting the formation of a nucleate boiling regime.

It is known to use a Teflon® coating on the interior of cryogenic transfer lines to speed cooling thereof, however, it is not taught or suggested to use Teflon on a HTS element to enhance heat transfer from the HTS element to a surrounding liquid cryogen cooling bath.

It would therefore be desirable to employ a simple, reliable and effective apparatus to speed up the temperature recovery after a fault condition has occurred in an HTS element, within an FCL system.

### BRIEF DESCRIPTION

Briefly, in accordance with one embodiment of the present invention, a fault current limiter, having a heat transfer medium, employs a high temperature superconductor based element which has a coating material encapsulating the high temperature superconductor based element to form an intermediate boundary layer between the HTS element and the heat transfer medium, wherein the coating material has a high thermal resistance. The coating material has a thickness which enables it to maintain substantially during recovery cooling a temperature gradient between the coated surface of the high temperature superconductor and the surface of the coating in contact with the cryogenic fluid so as to develop a temperature difference between the cooled surface of the coating (T_{wall}) and the saturation temperature of the cryogen bath (Tₛₐₜ), wherein substantially all heat transfer to the cryogen bath occurs at the nucleate heat transfer rate. The thickness of the coating material is selected so that the heat flux through the coating is substantially equal to the heat transfer from the coating material to the cryogen bath.

### DRAWINGS

These and other features, aspects, and advantages of the present invention will become better understood when the following detailed description is read with reference to the accompanying drawings in which like characters represent like parts throughout the drawings, wherein:

FIG. 1 is a generalized prior art plot of a boiling heat transfer curve for liquid nitrogen at 1 atmosphere pressure.

FIG. 2 is a prior art thermal schematic of the film boiling interface between the HTS element and liquid nitrogen bath when the HTS element is in direct contact with the cryogen liquid and at a temperature sufficiently high to support the stable formation of a vapor film.

FIG. 3 is a thermal schematic of the desired nucleate boiling interface between the HTS element with an intermediate boundary layer coating and the liquid cryogen bath of the present invention.

FIG. 4 is a plot of modeled results of the cool-down of a fault current limiter element from 300 K to 110 K in direct contact with liquid nitrogen, as compared with cooling and an intermediate boundary layer of 0.38 mm thick Kapton polyimide insulation barrier of the present invention.

FIG. 5 is a plot of modeled results of the cooling time versus Teflon thickness of a one inch diameter stainless steel rod having an Teflon film intermediate boundary layer.

FIG. 6 is a plot of modeled results of the energy dissipation expressed in Watts per cm² versus Teflon thickness of a 1 inch diameter stainless steel rod with a Teflon film intermediate boundary layer.

FIG. 7 is a cryogenic cooling system with a HTS element with an encapsulating coating material submerged in a cooling medium of the present invention.

### DETAILED DESCRIPTION

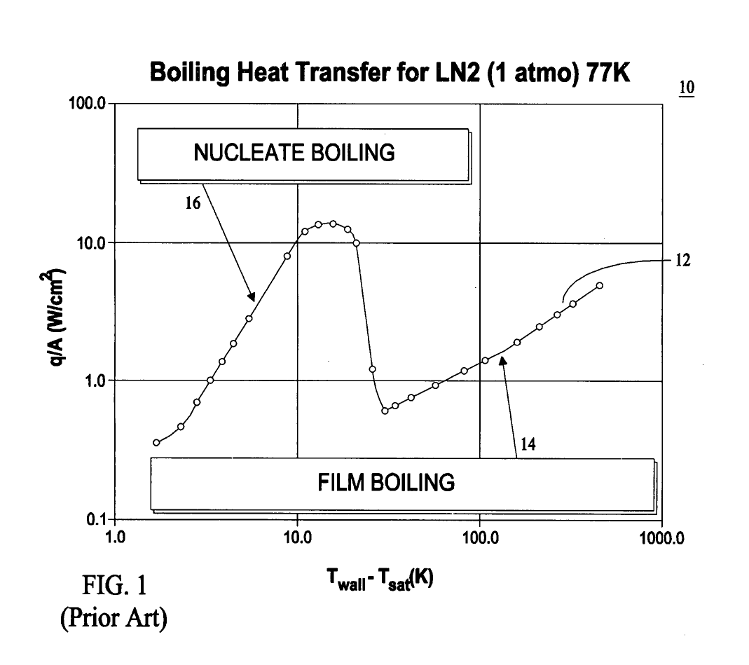

During a fault condition on the electric grid and the resultant electrical load transient, the temperature of an HTS element in the Fault Current Limiter (FCL) structure rises rapidly, within milliseconds, to well above the critical temperature T_{c} of the HTS material where it transitions from a superconductor to the non-superconducting (resistive) state. In order to return to the normal operating superconducting condition, the HTS element must be re-cooled to restore its superconducting properties. The heating is essentially adiabatic during the fault transient. Additional heat load may be encountered if normal load current is reapplied after the fault to the FCL, with some or all of the current flowing in the HTS element, the remaining current being diverted into a parallel circuit. The heated HTS element is cooled by contact with the liquid cryogen coolant, which is typically liquid nitrogen, but can be other liquid cryogens depending on the operating temperature of the FCL system. Because the temperature rises so rapidly in the HTS element, the resulting difference in temperature at the HTS wall and the coolant temperature results in the initiation of film boiling heat transfer which generally has an inherently lower heat transfer rate 14 than the more ideal nucleate boiling heat transfer 16 as illustrated in plot 10, line 12 of FIG. 1. This invention is directed to an intermediate boundary layer coating material between the heated HTS element and the liquid cryogen cooling medium. By modifying the thermal resistance through adjusting the thickness of this intermediate boundary layer, most of the temperature drop between the heated HTS element and the liquid cryogen cooling is in the intermediate boundary layer. This results in a sufficiently low ΔT at the intermediate layer, i.e. cryogen interface, that supports a higher heat transfer rate of the nucleate boiling state 16, resulting in a simple and reliable solution to the thermal problem identified herein.

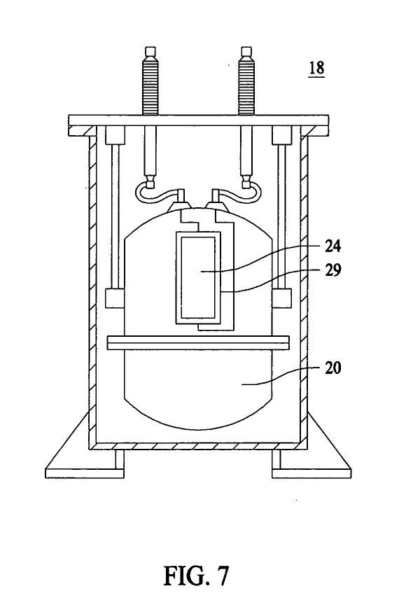

A fault current limiter in the present system 18 may be a FCL comprising a superconducting based element or composite 24, such as BSCCO-2223, YBCO, BSCCO2212 or others, which has at least one high temperature superconductor element 24 which may be coupled in parallel with a shunt coil (not shown). See, for example, FIG. 7. The shunt coil may be physically disposed around the HTS 24 in such a way so that the magnetic field generated by the current in the coil is uniformly applied to the HTS or the parallel shunt coil may be placed independent of the superconductor element 24. Under normal operating conditions, the superconducting element 24 will have essentially no resistance and thus effectively all current will flow through it. Consequently, there is virtually no voltage drop across the whole arrangement and the parallel-connected shunt coil will have no current flowing through it. Once there is a fault however, the current surge will exceed the critical current level of the superconductor element 24 and cause it to quench quickly (within a few msec), thus generating a sufficiently large voltage drop across the shunt coil which results in a substantial part of the overall current being diverted into the shunt coil. If the shunt coil is disposed around the superconductor element, the resulting current in the shunt coil will generate a magnetic field that is uniformly applied to the superconductor 24, which acts to ensure a uniform quench of the superconductor. The shunt will also act to limit the voltage generated by the superconductor 24 and share the total current to insure that the superconductor 24 does not overheat and can return to its normal state once the fault has been removed. The fault current limiter 24 may also have a trigger coil (not shown) electrically coupled in series or in parallel or a combination of series and parallel with the HTS element. One exemplary embodiment of the FCL is illustrated in U.S. Pat. No. 6,664,874, which is assigned to assignee of the present invention and herein incorporated by reference.

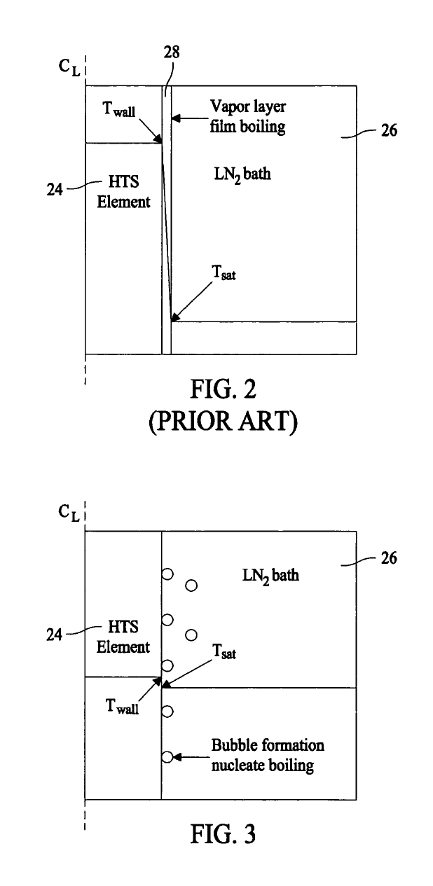

The mechanism for the HTS element 24 to cool during film boiling 14 in liquid nitrogen 26 is shown in prior art FIG. 2. HTS wall temperature minus liquid cryogen saturation temperature, i.e. ΔT, is (T_{wall}−Tₛₐₜ), is the difference in temperature between the wall of the HTS element (T_{wall}) and the saturation temperature (Tₛₐₜ), of the liquid nitrogen bath 26. Modifications to this cooling curve are made for subcooled and pressurized conditions, but the general trends as shown in FIG. 1 are present under all expected operating scenarios. As the HTS element 24 nearly instantaneously rises in temperature, the ΔT immediately goes into the film boiling regime, wherein it slowly cools until ΔT drops to approximately 32 K where cooling then transitions to nucleate boiling. It should be emphasized that the bath may be in conditions other than saturated at one atmosphere as illustrated in FIG. 1. The bath may also be pressurized or reduced pressure or subcooled. The shape of the heat transfer curves maintain the general characteristics shown in FIG. 1, although shifted. Geometry and morphology of the surface or flow rate of the cryogen can also play a role shifting the position of the curves.

FIG. 2 shows the mechanism of film boiling with the formation of a vapor layer on the surface of the HTS element 24 during heating which is directly immersed in a liquid heat transfer medium 26 within a cryogenic cooling system, such as is caused during a fault condition and thereafter. This vapor layer 28 has limited thermal conductivity and therefore limits the heat transfer from the heated HTS element 24 to the cryogen bath 26.

In order to achieve the desired nucleate boiling regime at the interface, as is shown in FIG. 3, the temperature difference at the interface (T_{wall}−Tₛₐₜ) must be reduced below the critical level, approximately 12 K, as in the case at one atmosphere liquid nitrogen. This can be achieved by adding a thin layer or coating 29 of a low thermal conductivity material on substantially the entire surface area of the HTS element 24 that is exposed to the liquid bath 26 to introduce a thermal resistance at the interface. This coating has a small thermal capacity due to its small mass. The high thermal resistance results in a large temperature drop across the coating, wherein the temperature of the coating at the liquid nitrogen surface is low enough to sustain nucleate boiling. By proper selection of the coating thickness one can balance the heat flux across the coating with a comparable heat flux into the liquid nitrogen by nucleate boiling 16, illustrated in FIG. 1. By way of example, and not limitation, the coating material is selected from the group of thermal insulations including PTFE, TFE, FEP, polyvinylformal, epoxies, and ceramic glass. These thermal insulators may be polymer based insulators or organic insulators. In an alternative embodiment the coating material may be selected from the group of high thermal resistance metallic materials including stainless steel, nickel based alloys, iron based alloys and titanium alloys.

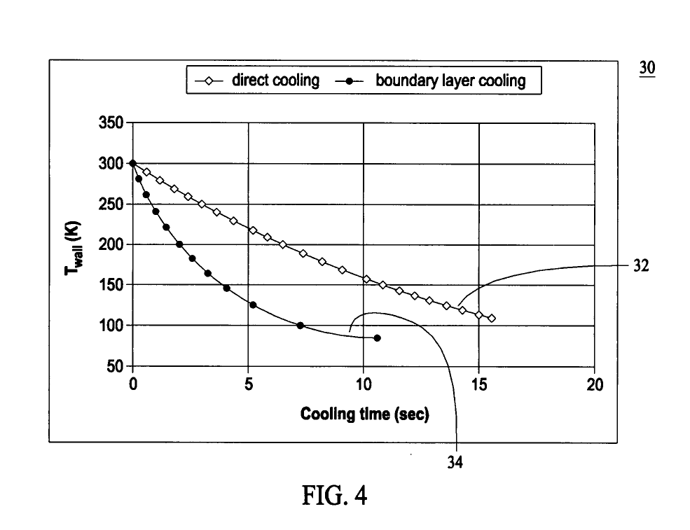

Preliminary modeling analysis has been conducted considering a BSCCO-2212 melt cast HTS element 24, which in one exemplary embodiment is 1.6 mm thick, which is assumed to have been heated essentially adiabatically to 300 K during a transition fault. The analysis provides for symmetric cooling from one face with the internal temperature of the HTS element dropping as energy is removed. No additional heating from re-applied current load is considered. For direct cooling in the liquid nitrogen bath, the HTS element 24 can be treated as a lump parameter system (Biot number, Bᵢ<0.1) over most of the cooling range from 300K to approximately 140 K. Below 140 K, the HTS element cools slightly faster at the wall than the core. Upon final analysis, the difference in core to wall temperature at 110 K is only approximately 2 K. The cooling curves in plot 30 illustrated in FIG. 4 show that direct cooling of the HTS element by film boiling liquid nitrogen from 300 K to 110 K takes approximately 15 seconds, as illustrated by line 32.

The model was then used to consider the impact a 0.38 mm thick intermediate boundary layer Kapton® polyimide coating 29 applied between the HTS element 24 and the 77 K liquid nitrogen bath 26. The HTS wall temperature was determined iteratively, such that the heat flux through the boundary layer 29 equaled the heat flux into the liquid nitrogen 26 utilizing nucleate boiling state 16 identified in FIG. 1. Lump parameter analysis was used throughout the temperature range due to the small differences noted above. The resultant cool down of the HTS element 24 with an immediate boundary layer proceeded much faster, reaching the 110 K temperature in approximately six seconds as compared to approximately 15 seconds for the direct cooling by liquid nitrogen, as shown in line 34 of FIG. 4. A final temperature of 80° K was reached in under 11 seconds. The thickness of the boundary layer may be further selected to optimize and thus, improve cooling rates. The current analysis indicates that a maximum cooling rate of approximately 9.5 Watts/cm² is possible.

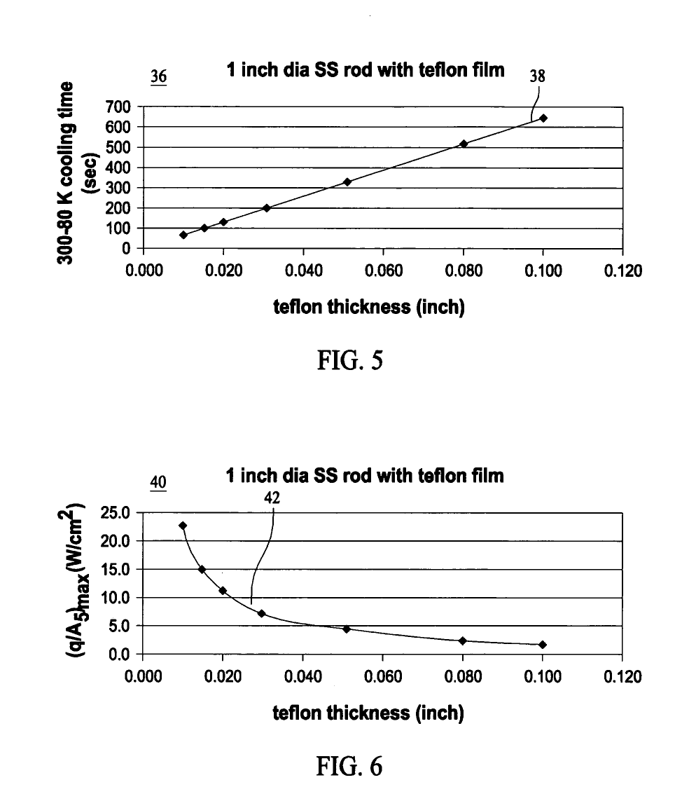

To illustrate the impact of the thickness of the intermediate coating on the heat transfer rate to the liquid cryogen bath, a model was run using a 1 inch diameter stainless steel rod (emulating the superconducting element) having an intermediate boundary layer 29 of Teflon film wherein the Teflon has a varied number of thicknesses as indicated in FIGS. 5 and 6 and illustrated in plots 36 and 40 respectively. As the Teflon thickness is measured in a range from about 0.01 inches to about 0.1 inches the cooling time of the stainless steel rod from 300 K to 80 K increases from about 80 seconds to about 650 seconds, as shown by line 38. Converting these numbers into a transfer rate expressed in Watts/cm², as illustrated in FIG. 6, the heat transfer rate 42 goes from about 22 to about 2.5 Watts/cm² when the Teflon thickness is increased from about 0.01 inches to about 0.1 inches. It is clear from these illustrations that as the intermediate boundary layer 29 is reduced the cooling time is improved. This trend can be carried over to the case of a superconducting HTS element encapsulated by an intermediate boundary layer.

The previously described embodiments of the present invention have many advantages, including higher heat transfer rates that enable this invention to have greater design flexibility to be able to handle higher fault loads, including the ability to recover under load, and enhance the speed of recovery after a fault for a given fault load. The boundary layer materials thickness and composition can be adjusted to optimize performance for a given set of operating parameters. Adding the intermediate boundary layer 29 to the HTS element 24 can improve the cooling rate of the fault current limiter superconductor elements by two fold, which provides a broader range of design options for handling the fault load. It is also understood that the HTS element and FCL described herein may be part of a broader matrix type fault current limiter, having a plurality of HTS elements within the MFCL as described, for example, in U.S. Pat. No. 6,664,875.

FIG. 7 illustrates a cryogenic cooling system having an HTS element 24 encapsulated with a high thermal resistance coating material 29 and disposed within a liquid cryogen heat transfer medium 20 such as liquid nitrogen. The cooling system 18 operates to regulate the temperature of the heat transfer medium 20. The coating material 29 has a thickness which enables it to minimize the retained heat in the HTS element 24 during recovery from a fault condition, wherein substantially all heat transfer from the encapsulated HTS element to the liquid cryogen heat transfer medium 20 occurs at the nucleate boiling heat transfer rate.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A superconducting device having a liquid cryogen heat transfer medium comprising:
a high temperature superconductor; and
a coating material encapsulating said high temperature superconductor to form an intermediate boundary layer between said high temperature superconductor and the heat transfer medium;
wherein said coating material has a high thermal resistance; and
wherein the thickness of said coating material is selected so as to develop a temperature gradient across said coating material such that the difference in temperature between the surface of said coating material in contact with the liquid cryogen and other portions of the liquid cryogen is limited to cause the formation of nucleate boiling and its associated high heat transfer rate when the temperature of said high temperature superconductor is elevated above the temperature of the heat transfer medium.

2. The superconducting device as recited in Claim 1, wherein said coating material is selected from the group of thermal insulations consisting of PTFE, TFE, FEP, polyvinylformal, epoxies, and ceramic glass.

3. The superconducting device as recited in claim 1, wherein said coating material is selected from the group of high thermal resistance metallic materials consisting of stainless steel, nickel based alloys, iron based alloys and titanium alloys.

4. The superconducting device as recited in claim 1, wherein the heat transfer medium is liquid nitrogen.

5. The superconducting device as recited in claim 1, wherein the superconducting device is disposed in a cryogenic cooling system, wherein said cooling system is adapted to regulate the temperature of the heat transfer medium.

6. The superconducting device as recited in claim 1, wherein said intermediate boundary layer has a thickness in the range from about 0.01 inches to about 0.1 inches.

7. A cryogenic cooling system having at least one HTS element and having a liquid cryogen heat transfer medium, the cryogenic cooling system comprising:
a coating material encapsulating the at least one HTS element and adapted to interact with the cryogenic cooling system to form an intermediate boundary layer between the surface of the at least one HTS element and the heat transfer medium;
wherein said coating material has a high thermal resistance; and
wherein the thickness of said coating material is selected to develop a temperature gradient across said coating material such that the difference in temperature between the surface of said coating material in contact with the liquid cryogen and other portions of the liquid cryogen is limited to causing the formation of nucleate boiling and its associated high heat transfer rate when the temperature of the at least one HTS element is elevated above the temperature of the heat transfer medium.

8. The cryogenic cooling system as recited in claim 7, wherein said coating material is selected from the group of thermal insulations consisting of PTFE, TFE, FEP, polyvinylformal, epoxies, and ceramic glass.

9. The cryogenic cooling system as recited in claim 7, wherein said coating material is selected from the group of high thermal resistance metallic materials consisting of stainless steel, nickel based alloys, iron based alloys and titanium alloys.

10. The cryogenic cooling system as recited in claim 7, wherein the heat transfer medium is liquid nitrogen.

11. The cryogenic cooling system as recited in claim 7, wherein said intermediate boundary layer has a thickness in the range from about 0.01 inches to about 0.1 inches.

12. A fault current limiter having a liquid cryogen heat transfer medium comprising:
a high temperature superconductor; and
a coating material encapsulating said high temperature superconductor to form an intermediate boundary layer between said high temperature superconductor and the heat transfer medium;
wherein said coating material has a low thermal resistance; and
wherein the thickness of said coating material is selected to develop a temperature gradient across said coating material such that the difference in temperature between the surface of said coating material in contact with the liquid cryogen and other portions of the liquid cryogen is limited to cause the formation of nucleate boiling and its associated high heat transfer rate when the temperature of said high temperature superconductor is elevated above the temperature of the heat transfer medium.

13. The fault current limiter as recited in claim 12, wherein said coating material is selected from the group of thermal insulations consisting of PTFE, TEE, FEP, polyvinylformal, epoxies, and ceramic glass.

14. The fault current limiter as recited in claim 12, wherein said coating material is selected from the group of thermal resistance metallic materials consisting of stainless steel, nickel based alloys, iron based alloys and titanium alloys.

15. The fault current limiter as recited in claim 12, wherein the fault current limiter is disposed in a cryogenic cooling system, wherein said cooling system is adapted to regulate the temperature of the heat transfer medium.

16. The fault current limiter as recited in claim 12, wherein the heat transfer medium is liquid nitrogen.

17. The fault current limiter as recited in claim 12, wherein said intermediate boundary layer has a thickness in the range from about 0.01 inches to about 0.1 inches.

18. A method of manufacturing a superconducting device comprising the steps of:
applying a high thermal resistance coating material to encapsulate the superconducting device, said coating material having a predetermined thickness;
wherein the predetermined thickness of said coating material is selected so as to develop a temperature gradient across said coating material such that the difference in temperature between the surface of said coating material in contact with the liquid cryogen and other portions of the liquid cryogen is limited to cause the formation of nucleate boiling and its associated high heat transfer rate when the temperature of the superconducting device is elevated above the temperature of a surrounding heat transfer medium.

19. The method of manufacturing as recited in claim 18, wherein said coating material is selected from the group of thermal insulations consisting of PTFE, TFE, FEP, polyvinylformal, epoxies, and ceramic glass.

20. The fault current limiter as recited in claim 18, wherein said coating material is selected from the group of high thermal resistance metallic materials consisting of stainless steel, nickel based alloys, iron based alloys and titanium alloys.

21. The method of manufacturing as recited in claim 18, wherein said coating material has a thickness in the range from about 0.01 inches to about 0.1 inches.
